(19) United States
(12) Patent Application Publication
(10) Pub. No.: US 2025/0135701 A1
(43) Pub. Date: May 1, 2025

(54) METHOD OF MANUFACTURING ENCAPSULATION FILM

(71) Applicant: LG CHEM, LTD., Seoul (KR)

(72) Inventors: Kwang Hui CHOI, Daejeon (KR); Beom Doo SEO, Daejeon (KR); Dong Hwan RYU, Daejeon (KR); Jae Seol RYU, Daejeon (KR); Won Gu CHOI, Daejeon (KR); Jhin Yeong YOON, Daejeon (KR)

(21) Appl. No.: 18/686,714

(22) PCT Filed: Dec. 1, 2022
(86) PCT No.: PCT/KR2022/019400

§ 371 Date: Feb. 26, 2024

(30) Foreign Application Priority Data
Dec. 1, 2021 (KR) 10-2021-0170471

(51) Int. Cl. B29C 48/40; B29K 9/00; B29K 105/00; B29L 31/34; H10K 50/844

(52) U.S. Cl. CPC B29C 48/40; H10K 50/844; B29C 2948/92514; B29C 2948/9259; B29C 2948/92704; B29K 2009/00; B29K 2105/0088; B29K 2105/0094; B29L 2031/3481

(57) ABSTRACT

A method of manufacturing an encapsulation film, the method including preparing a solventless type encapsulation composition by mixing an encapsulation resin and a moisture adsorbent in a single step; and preparing an encapsulation layer by extruding the encapsulation composition at a temperature of 90° C. or more, a method of manufacturing an organic electronic device manufacturing method using same, and provides a method of manufacturing an encapsulation film having a structure capable of blocking moisture or oxygen flowing into an organic electronic device from the outside, and enabling long-term reliability of the organic electronic device to be ensured.

### CROSS-REFERENCE TO RELATED APPLICATIONS

This application is a National Stage Application of International Application No. PCT/KR2022/019400 filed on Dec. 1, 2022, which claims priority from Korean Patent Application No. 10-2021-0170471, filed on Dec. 1, 2021.

### TECHNICAL FIELD

The present application relates to a method of manufacturing an encapsulation film.

### BACKGROUND ART

An organic electronic device (OED) means a device comprising an organic material layer that generates alternate current of charges using holes and electrons, and an example thereof can include a photovoltaic device, a rectifier, a transmitter, and an organic light emitting diode (OLED), and the like.

The organic light emitting diode (OLED) among the above organic electronic devices has less power consumption and faster response speed than existing light sources, and is advantageous for thinning of a display device or illumination. In addition, the OLED has spatial usability and thus is expected to be applied in various fields covering various portable devices, monitors, notebooks, and TVs.

In commercialization and application expansion of the OLED, the most important problem is a durability problem. The organic materials and the metal electrodes, and the like included in the OLED are very easily oxidized by external factors such as moisture. Therefore, an encapsulation film with maximized moisture barrier properties is required.

### DISCLOSURE

### Technical Problem

The present application provides a method of manufacturing an encapsulation film that has a structure capable of blocking moisture or oxygen flowing into an organic electronic device from the outside, and long-term reliability of the organic electronic device can be ensured.

The technical problems of the present application are not limited to the technical problems as mentioned above, and other technical problems not mentioned will be clearly understood by those skilled in the art from the following description.

### Technical Solution

The present invention can be subjected to various modifications and can have various examples, where specific examples will be illustrated in the drawings and described in detail. However, this is not intended to limit the present invention to specific embodiments, and it should be understood to include all modifications, equivalents and substitutes included in the spirit and scope of the present invention.

When an element such as a layer, a region or a substrate is referred to as being present “on” another component, it will be possible to appreciate that it can be present directly on another element or an intermediate element can also be present therebetween.

The terms used in the present application are only used to describe specific examples, which are not intended to limit the present invention. A singular expression includes a plural expression, unless the context clearly dictates otherwise. In the present application, it should be understood that the term such as “comprise” or “have” is intended to designate that a feature, number, step, operation, component, part, or combination thereof described in the specification exists, but it does not preclude one or more other features, or existence or addition possibility of numbers, steps, operations, components, parts or combinations thereof in advance.

Unless otherwise defined, all terms used herein, including technical or scientific terms, have the same meanings as those commonly understood by those having ordinary knowledge in the art to which the present invention belongs. Terms such as those defined in commonly used dictionaries should be interpreted as having meanings consistent with the meanings in the context of the related art, which are not interpreted in ideal or excessively formal meanings, unless explicitly defined in the present application.

The present application relates to a method of manufacturing an encapsulation film. The encapsulation film can be applied to seal or encapsulate, for example, an organic electronic device such as an OLED.

In this specification, the term “organic electronic device” means an article or device having a structure comprising an organic material layer that generates alternate current of charges using holes and electrons between a pair of electrodes facing each other, and an example thereof can include, but is not limited to, a photovoltaic device, a rectifier, a transmitter, and an organic light emitting diode (OLED), and the like. In one example of the present application, the organic electronic device can be an OLED.

In an embodiment of the present application, the manufacturing method of the encapsulation film can comprise a step of preparing a solventless type encapsulation composition by mixing an encapsulation resin and a moisture adsorbent in a single step.

Here, the solventless type means a case in which a solvent is not substantially included or a solvent is included in an amount of 0.1 wt % or less, or 0.01 wt % or less in the total encapsulation composition. That is, the encapsulation composition comprises a solid content of 99 wt % or more, or 100 wt %, where the present application provides an encapsulation film capable of forming a film only with raw materials having a solid content of 99 wt % or more, or 100 wt % without a separate solvent.

In addition, the matter of mixing an encapsulation resin and a moisture adsorbent in a single step means that the encapsulation resin and the moisture adsorbent are simultaneously introduced thereto, or immediately, within at least 5 minutes or 3 minutes, or within 100 seconds after any one is introduced, the other is continuously introduced thereto, and formulated. That is, it is distinguished from a process of dissolving the moisture adsorbent using a solvent or the like to prepare a separate mixture, and separately mixing the mixture, in which the moisture adsorbent is dissolved, with a resin or a solution, in which the resin is dissolved, to prepare a sealing material composition.

It is one of the key challenges in the encapsulation film for OLEDs to secure long-term reliability by maximizing moisture barrier properties. In order to secure moisture barrier properties, the encapsulation film must necessarily comprise a moisture adsorbent capable of removing moisture or humidity penetrating the encapsulation film. In order to maximize moisture barrier properties, especially, the moisture adsorbent must be sufficiently dispersed in the composition. Here, the dispersion means a state where particles are not subjected to aggregation, such as formation of lumps, and are uniformly scattered, where if the dispersion is good, the particles can be in a state of being separated from one another.

Conventionally, in order to prepare an encapsulation composition, a solvent-type resin solution was prepared by dissolving an encapsulation resin in a solvent, and a mixture, in which a moisture adsorbent was dispersed in a solvent using a dispersing agent, was introduced into the resin solution, whereby a method of forming a coating liquid, in which the resin and the moisture adsorbent were formulated, was adopted, and thus two or more steps were required to form the coating liquid. That is, in order to increase the dispersibility of the moisture adsorbent, a separate dispersant such as an organic acid had to be used, but due to the high viscosity characteristics of the coating liquid, there was a limit to improving the dispersibility of the moisture adsorbent even when a separate dispersant was used. Furthermore, when a mixture was formed using a solvent, the solvent remained inside the film, even if a solvent drying process was performed thereafter, whereby there was a problem of damaging organic electronic elements due to some non-volatilized solvents. Therefore, as an encapsulating layer is manufactured through extrusion to be described below while using a solventless-type encapsulation composition by mixing an encapsulation resin and a moisture adsorbent in a single step, the present application can provide an organic electronic element capable of effectively securing long-term reliability while maximizing dispersibility of a moisture adsorbent.

In one example, the step of preparing an encapsulation composition can be performed under high temperature conditions, and as one example, it can be performed at a temperature of 50° C. or more and a pressure of 5 bar or more. The temperature can be higher than the melting point of the resin, and as one example, it can be 60° C. or more, 70° C. or more, 80° C. or more, 90° C. or more, 100° C. or more, 110° C. or more, 120° C. or more, 125° C. or more, 130° C. or more, 135° C. or more, 140° C. or more, 145° C. or more, or 150° C. or more, where the upper limit of the temperature can be appropriately adjusted to a temperature at which the components introduced into the encapsulation composition do not thermally decompose, but as one example, it can be 200° C. or less, or 180° C. or less. In addition, the pressure can be 7 bar or more, 10 bar or more, 13 bar or more, 15 bar or more, 17 bar or more, or 20 bar or more, and the upper limit of the pressure can be appropriately adjusted according to the purpose, but as one example, it can be 30 bar or less. Although not limited thereto, as one example, the step of preparing an encapsulation composition can be one kneaded by putting it into a kneading machine such as a kneader or Banbury, and the temperature of 50° C. or more and the pressure of 5 bar or more can be the temperature or pressure inside the kneading machine. As described above, in the present application, as the preparation step of the encapsulation composition is performed at a certain temperature or more, the components in the encapsulation composition are melt-kneaded, whereby the dispersibility of the moisture adsorbent is further improved, and the compatibility between the components in the composition is excellent, whereby the workability for the extruding process can also be shown to be excellent.

In one embodiment, the manufacturing method of the encapsulation film according to the present application can comprise a step of preparing an encapsulation layer by transferring the above-prepared encapsulation composition to an extruder, and compounding and extruding it at a temperature of 90° C. or more.

The extrusion temperature in the step of preparing an encapsulation layer can mean an internal temperature of the extruder, or a molding temperature. Here, the internal temperature of the extruder can mean a temperature in a section where the encapsulation composition transferred from the kneading machine to the extruder is blended while moving in a discharge part direction by a screw in the extruder. In addition, the molding temperature refers to a temperature of the molding part mounted on the discharge part of the extruder, which can mean, as one example, a temperature of a T-die. The molding temperature can mean a temperature in a section where it is ejected and molded in the form of a film by a molding part.

That is, the encapsulation composition according to the present invention is primarily kneaded in a kneader to uniformly disperse the moisture adsorbent, transferred to an extruder, and secondarily kneaded by a screw mounted inside the extruder, so that the dispersion degree of the moisture adsorbent can be further improved.

Although not limited thereto, as one example, the extruder can be a single-screw extruder or a twin-screw extruder, but the twin screw extruder having excellent productivity and uniformity is preferred. In addition, the type or rotation direction, and the like of the screw in the twin-screw extruder can be appropriately selected according to the ingredients to be introduced.

In one example, the temperature at which the encapsulation layer is produced by extrusion can be 100° C. or more, 110° C. or more, 120° C. or more, 125° C. or more, 130° C. or more, 135° C. or more, 140° C. or more, 145° C. or more, 150° C. or more, 155° C. or more, 160° C. or more, 165° C. or more, 170° C. or more, 175° C. or more, or 180° C. or more, and the upper limit of the temperature can be appropriately adjusted to a temperature at which the components introduced into the encapsulation composition do not thermally decompose, but as one example, it can be 200° C. or less, or 180° C. or less. As one example, the internal temperature of the extruder can be 140° C. or more, and the molding temperature can be 150° C. or more. In addition, as one example, the difference between the internal temperature of the extruder and the molding temperature can be within 50° C. or 30° C. In the present application, as the internal temperature of the extruder satisfies the above range, the moisture adsorbent can be uniformly dispersed in the encapsulation composition, and as the molding temperature is controlled to the above range, the properties of the film can be improved.

Also, in one example, the step of preparing an encapsulation layer by extrusion is performed at a high pressure of 5 bar or more, so that the viscosity of the encapsulation composition can be controlled within a range to be described below, and accordingly the dispersibility of the moisture adsorbent can be further improved. Although not limited thereto, as one example, the pressure in the extrusion step can be 6 bar or more, 7 bar or more, 10 bar or more, 11 bar or more, 12 bar or more, 13 bar or more, 14 bar or more, 15 bar or more, 16 bar or more, 17 bar or more, 18 bar or more, or 20 bar or more, and the upper limit of the pressure can be appropriately adjusted according to the above purpose, but can be, as one example, 30 bar or less.

In one example, the rotation speed of the screw in the extruder can be in a range of 100 to 400 rpm, 150 to 350 rpm, 170 to 320 rpm, 200 to 300 rpm or 230 to 270 rpm. In the present application, the moisture adsorbent can be uniformly dispersed in the encapsulation composition even in a solventless type by using a strong shear force according to the screw rotation of the extruder.

In one embodiment, the manufacturing method according to the present application can further comprise a curing step of performing electron beam or UV irradiation on the extruded encapsulation layer. The electron beam or UV irradiation can be performed by a known method.

In one example, the encapsulation layer manufactured according to the manufacturing method is a single layer, but in Gaussian curve fitting for a distribution of the moisture adsorbent along the thickness (depth) direction in the encapsulation layer, a position distribution (σ value) of the moisture adsorbent with respect to the thickness direction can be 2 or less.

As one example, in Gaussian curve fitting for the thickness distribution of the moisture adsorbent, the position distribution (σ value) of the moisture adsorbent with respect to the thickness direction can be 1.9 or less, 1.8 or less, 1.7 or less, 1.6 or less, 1.5 or less, 1.4 or less, 1.3 or less, 1.2 or less, 1.1 or less, 1 or less, 0.9 or less, 0.8 or less, 0.7 or less, 0.6 or less, 0.5 or less, 0.4 or less, 0.3 or less, 0.2 or less, 0.15 or less, or 0.1 or less, and the lower limit is not significantly limited, but it can be 0.001 or more.

Here, the Gaussian curve fitting represents a function for the thickness of the encapsulation layer, which is as shown in Equation 1 below.

$$f ( x ) = A exp ( \frac{- {( x - \overline{x} )}^{2}}{2 σ} ) + b \qquad [ Equation 1 ]$$

In Equation 1, A and b are constants related to absolute amounts of the moisture adsorbent, x̅ is the average position of the moisture adsorbent with respect to the thickness direction, and σ is the position distribution of the moisture adsorbent with respect to the thickness direction.

As the σ value in the Gaussian curve fitting for the thickness distribution of the moisture adsorbent satisfies the specific range as described above, the moisture adsorbent can be included in a high content in the region corresponding to the central portion of the encapsulation film in the thickness direction, and accordingly while moisture adsorption properties are excellent, at the same time, the pressure-sensitive adhesion properties can also be improved.

That is, the encapsulation layer can comprise a first region, a second region, and a third region in which the concentrations of the moisture adsorbent are different along the thickness direction, and the encapsulation layer is a single layer, which is not composed of a laminated structure having a plurality of layers, but the single layer can be optionally divided into regions depending on the concentrations of the moisture adsorbent. As one example, the first region, the second region, and the third region constituting the monolayered encapsulation layer can have different moisture adsorbent contents. At this time, in relation to the region division according to the contents of the moisture adsorbent, the contents of the moisture adsorbent at the interfaces of the respective regions can continuously change, so that the interfaces in the respective regions need not necessarily to be clearly distinguished.

In one example, the second region can comprise the moisture adsorbent in a content higher than those of the first region and the third region. That is, the second region can be a region having a higher moisture adsorbent content than the first region and the third region. In this case, it is sufficient if the moisture adsorbent content of the first region and the third region is lower than that of the second region, where the moisture adsorbent contents of the first region and the second region can be the same or different.

FIG. 1 shows a monolayered encapsulation layer divided into regions according to the contents of the moisture adsorbent, and referring to FIG. 1, the second region (22), which is a region with a high moisture adsorbent content, can be interposed between the first region (21) and the third region (23), having low concentrations of the moisture adsorbent. In other words, the first region (21) and the third region (23), which are regions with low moisture adsorbent contents, form the uppermost part or the lowermost part of the encapsulation layer (11), respectively, which can be located on the upper or lower surface, and directly contact other components to be in contact with the top or bottom of the encapsulation layer.

That is, according to the present invention, the moisture adsorbent included in the encapsulation layer can exist in a state in which it is not evenly distributed in the encapsulation layer in the form of particles. Here, the distribution relates to the way that particles fill a space, which is a concept distinct from dispersion. The evenly distributed state means a state that the moisture adsorbent is present at the same or substantially the same density in any part of the encapsulation layer or the encapsulation film, and thus the particles are spaced as far apart as possible to uniformly fill the space.

Meanwhile, when the moisture adsorbent is included in an excessive amount in an evenly distributed state in the encapsulation layer in contact with an organic electronic element, the moisture adsorbent is also present in an excess amount on the upper and lower surfaces of the encapsulation layer forming the uppermost portion and/or the lowermost portion, and in this case, the adhesion performance of the encapsulation layer is very low, so that there can be a problem that durability and reliability of the organic electronic element deteriorate.

Therefore, conventionally, a multilayer structure comprising at least two or more encapsulation layers was used as an encapsulation film. That is, an OLED encapsulating material must comprise a layer having moisture barrier properties as an essential component in order to secure excellent moisture barrier properties, and the layer having moisture barrier properties requires excellent adhesion properties with upper and/or lower components. A method of separately manufacturing a layer having moisture barrier properties and a layer having adhesion properties, and then attaching the respective layers to each other to integrate them into one was considered. However, according to the above method, it is necessary to manufacture a plurality of layers in order to secure required functions, so that problems such as price increase, process complexity, and thinning efficiency decrease may be caused. For example, when an encapsulation film having a multi-layer structure is applied on an organic electronic element, it is designed such that the first encapsulation layer facing the organic electronic element does not comprise a moisture adsorbent, or comprise it in a small amount, even if it present, and the second encapsulation layer located on the opposite side to the side facing the organic electronic element comprises the moisture adsorbent in a large amount, whereby the adhesion properties have been secured from the first encapsulation layer in contact with the organic electronic element, and the moisture barrier properties have been secured from the second encapsulation layer.

However, the encapsulation layer according to the present application contains the moisture adsorbent at a high concentration in the central portion in the thickness (depth) direction of the encapsulation layer, and contains the moisture adsorbent at a low concentration in both surfaces of the encapsulation layer, whereby the moisture adsorbent shows a specific distribution state, so that the present application comprises a monolayered encapsulation layer, thereby being capable of providing an encapsulation film having excellent barrier properties simultaneously while exhibiting an appropriate level of adhesion without a separate pressure-sensitive adhesive layer or adhesive layer. Therefore, the present application can provide an encapsulation film capable of exhibiting moisture barrier properties and pressure-sensitive adhesive properties as excellent performance using only a single layer.

Furthermore, in one example, the encapsulation layer of the present application can also be a single layer, but is not limited thereto, and can have a multi-layer structure comprising at least two or more encapsulation layers. In the case of comprising the two or more encapsulation layers, the encapsulation layer can comprise, upon encapsulating the organic electronic element, a first encapsulation layer facing the element, and a second encapsulation layer positioned on the opposite side to the side of the first encapsulation layer facing the element. In one embodiment, the encapsulation film comprises at least two or more encapsulation layers, where the encapsulation layer can comprise a first encapsulation layer facing the organic electronic element upon encapsulation and a second encapsulation layer not facing the organic electronic element. In addition, when two or more layers constitute an encapsulation layer, the compositions of the respective layers of the encapsulation layer can be the same or different. In one example, the encapsulation layer can comprise an encapsulation resin and/or a moisture adsorbent, and the encapsulation layer can be a pressure-sensitive adhesive layer or an adhesive layer. As one example, when the encapsulation film is applied on an organic electronic element, the first encapsulation layer, which is an encapsulation layer facing the organic electronic element, does not comprise a moisture adsorbent, or can comprise, even if it present, it in a small amount of 5 wt % or less based on the total weight of the moisture adsorbent, and a large amount of moisture adsorbent as described below can be included in the second encapsulation layer.

In one example, the metal pressure-sensitive adhesion force of the encapsulation layer can be 4,000 gf/in or more, 4,200 gf/in or more, 4,400 gf/in or more, 4,600 gf/in or more, 4,800 gf/in or more, 5,000 gf/in or more, 5,100 gf/in or more, 5,200 gf/in or more, 5,300 gf/in or more, 5,400 gf/in or more, or 5,5 gf/in or more. That is, as the encapsulation film according to the present application has different contents of the moisture adsorbent along the thickness direction as described above, and the first region or the third region, which is a region with a low content of the moisture adsorbent, is located at the upper or lower surface of the encapsulation layer, the encapsulation layer of the present application can have excellent metal pressure-sensitive adhesion force. As described below, the metal pressure-sensitive adhesion force is a pressure-sensitive adhesion force to the metal layer that can be added on the encapsulation layer, where after fixing the encapsulation film left for 30 minutes in a constant temperature and humidity room at 85±5° C. and 85±10% to a tensile machine (TA, Texture Analyzer), it can be measured in Tension Mode at a temperature of 25° C. and a tensile speed of 5 mm/min.

In one example, the encapsulation layer thus prepared can have a gel content of 60% or more as measured by General Equation 1 below.

$$Gel content ( \% ) = A / B \times 100 \qquad [ General Equation 1 ]$$

In General Equation 1 above, B is the mass of the encapsulation layer sample, and A shows the dry mass of an undissolved content of the encapsulation layer, wherein after the sample is immersed in toluene at 60° C. for 24 hours, and then filtered through a 200-mesh net, the undissolved content does not pass through the net. In this specification, the unit mesh can be an ASTM standard unit. It can be measured by setting the mass B of the encapsulation layer sample to 1 g. The gel content can be, for example, 63% or more, 65% or more, 67% or more, 70% or more, 72% or more, 75% or more, or 78% or more, and the upper limit can be, for example, 99% or less, 95% or less, 93% or less, 89% or less, 86% or less, 84% or less, 82% or less, or 80% or less. The present application can provide an encapsulation film having excellent curing physical properties as well as moisture barrier properties and stress absorption properties by adjusting the gel content.

In addition, the encapsulation layer according to the present application can have an acid value of 1 or less. The acid value can be, for example, 0.9 or less, 0.8 or less, or 0.7 or less, and the lower limit is not particularly limited, but can be 0.1 or more. Unlike moisture barrier properties, and occurrence of dark spots and occurrence of bright spots in organic electronic elements, which have been problematic heretofore, white spots generated in organic electronic elements have recently become a major cause of panel defects. By confirming that the mechanism for generating the white spots is due to the organic acid present in the encapsulation composition, and adjusting the cross-linking degree of the encapsulation layer matrix by the gel content together with the acid value of the encapsulation layer itself, the present application can have effectively suppressed the occurrence of white spots. In an embodiment, the organic acid reaches the organic electronic element in the form of ions, where white spots have been generated by shifting a threshold voltage in cracks that can be partially formed on the element. These technical problems can be prevented by adjusting the acid value and the gel content of the encapsulation layer encapsulating the top surface of the organic electronic element.

Furthermore, the encapsulation layer according to the present application can have excellent light transmittance for the visible ray region. In one example, the composition for encapsulation of the present application can exhibit light transmittance of 80% or more according to JIS K7105 standard after curing. For example, the composition for encapsulation can have light transmittance of 85% or more, 90% or more, 92% or more, or 93% or more for the visible ray region. The encapsulation layer of the present application can exhibit a low haze with excellent light transmittance. In one example, the encapsulation composition can have a haze of 5% or less, 4% or less, 3% or less, or 1% or less, as measured according to JIS K7105 standard after curing. The optical properties can be those measured at 550 nm using a UV-Vis Spectrometer.

Also, in one example, after curing the organic electronic element encapsulation layer, a yellowness degree (ΔYI, yellow index) value measured according to ASTM D 1003 standard using a chromaticity measuring instrument can be 1 or less, and the lower limit thereof is not greatly limited, but can be −2 or more.

In one example, when the purge and trap is performed on the encapsulation layer for 60 minutes at 100° C. using a Purge & Trap sampler (JAI JTD-505III)—GC/MSD system (Agilent 7890B/5977A) measuring instrument, and then the total outgas amount is measured using gas chromatography mass spectrometry, the measured outgas amount can be less than 400 ppm, and in detail, can be 300 ppm or less, 200 ppm or less, 100 ppm or less, 90 ppm or less, 80 ppm or less, 70 ppm or less, 50 ppm or less, 30 ppm or less, 20 ppm or less, or 10 ppm or less. That is, as the encapsulation layer according to the present invention comprises a composition to be described below, the outgas amount generated from the encapsulation layer is insignificant, so that the organic electronic element to which the encapsulation layer is applied can have excellent reliability.

In one embodiment, the encapsulation layer can have a thickness of 30 μm or more to 500 μm or less. The encapsulation layer of the present application can have a thickness of 30 μm or more, 33 μm or more, 35 μm or more, 40 μm or more, 43 μm or more, 45 μm or more, 47 μm or more, 50 μm or more, 52 μm or more, 55 μm or more, 57 μm or more, or 60 μm or more, and the upper limit is not particularly limited, but can be 500 μm or less, 400 μm or less, 300 μm or less, 250 μm or less, or 200 μm or less. The present application can maximize the moisture barrier properties by increasing the thickness of the encapsulation layer compared to the prior art, and simultaneously implementing the gel content at a desired level, and when panel warpage occurs in a harsh environment such as high temperature, it can also provide an organic electronic device having high reliability by absorbing the stress. Conventionally, the encapsulation film was formed by coating it to a certain thickness or more and then irradiating it with UV, but the UV did not penetrate to the inside of the film, so that there was a problem that the curing physical properties were significantly lowered, and the solvent remained inside the film, so that there was a problem that some non-volatized solvents and uncured materials damaged the organic electronic element. In particular, the encapsulation composition of the present application can be directly contacted with one side of the organic electronic element by sealing the top surface of the organic electronic element, where by using a solventless type with a composition to be described below without comprising a separate dispersant as the encapsulation composition, it is possible to further improve the reliability of the organic electronic element, and furthermore, by exhibiting an improved curing ratio even at a certain thickness or more, it is possible to implement excellent cured physical properties as well as moisture barrier properties and stress absorption.

In one embodiment, the encapsulation film (1) manufactured according to the present application can comprise an encapsulation layer (11) and a base material layer (12), as shown in FIG. 2. The encapsulation film can seal the top surface of the organic electronic element formed on the substrate.

In one example, the encapsulation composition of the present application can comprise an encapsulation resin. The encapsulation resin can be a cross-linkable resin or a curable resin, and in an embodiment, it can comprise an olefinic resin.

In one example, the encapsulation resin can have a glass transition temperature of less than 0° C., less than −10° C. or less than −30° C., less than −50° C., or less than −60° C. The lower limit is not particularly limited, and can be −150° C. or more. Here, the glass transition temperature can be a glass transition temperature after curing.

In one embodiment of the present invention, the encapsulation resin can be an olefin-based resin. In one example, the olefin-based resin can be a homopolymer of a butylene monomer; a copolymer obtained by copolymerizing a butylene monomer and another polymerizable monomer; a reactive oligomer using a butylene monomer; or a mixture thereof. The butylene monomer can include, for example, 1-butene, 2-butene or isobutylene. In one example, the olefinic resin can comprise an isobutylene monomer as the polymerization unit.

Other monomers polymerizable with the butylene monomers or derivatives can include, for example, isoprene, styrene, or butadiene and the like. By using the copolymer, physical properties such as processability and degree of cross-linking can be maintained and thus heat resistance of the adhesive itself can be secured when applied to organic electronic devices.

In addition, the reactive oligomer using the butylene monomer can comprise a butylene polymer having a reactive functional group. The oligomer can have a weight average molecular weight ranging from 500 to 5000 g/mol. Furthermore, the butylene polymer can be coupled to another polymer having a reactive functional group. The other polymer can be, but is not limited to, alkyl (meth)acrylate. The reactive functional group can be a hydroxyl group, a carboxyl group, an isocyanate group or a nitrogen-containing group. Also, the reactive oligomer and the other polymer can be cross-linked by a multifunctional cross-linking agent, and the multifunctional cross-linking agent can be at least one selected from the group consisting of an isocyanate cross-linking agent, an epoxy cross-linking agent, an aziridine cross-linking agent and a metal chelate cross-linking agent.

In one example, the encapsulation resin of the present application can comprise a copolymer of a diene and an olefinic compound containing one carbon-carbon double bond. Here, the olefinic compound can include butylene or the like, and the diene can be a monomer capable of polymerizing with the olefinic compound, and can include, for example, isoprene or butadiene and the like. For example, the copolymer of an olefinic compound containing one carbon-carbon double bond and a diene can be a butyl rubber.

In the encapsulation layer, the resin or elastomer component can have a weight average molecular weight (Mw) to an extent such that the pressure-sensitive adhesive composition can be formed into a film shape. For example, the resin or elastomer can have a weight average molecular weight of about 100,000 to 2,000,000 g/mol, 120,000 to 1,500,000 g/mol, 150,000 to 1,000,000 g/mol, 200,000 to 700,000 g/mol, 230,000 to 600,000 g/mol, 250,000 to 500,000 g/mol, or 300,000 to 470,000 g/mol or so. In this specification, the term weight average molecular weight means a value converted to standard polystyrene measured by GPC (gel permeation chromatograph), and unless otherwise specified, the unit is g/mol. However, the resin or elastomer does not necessarily have the above-mentioned weight average molecular weight. For example, in the case where the molecular weight of the resin or elastomer component is not in a level enough to form a film, a separate binder resin can be blended into the pressure-sensitive adhesive composition.

In one example, the encapsulation resin can be included in the encapsulation layer in an amount of 10 wt % or more, 13 wt % or more, 15 wt % or more, 17 wt % or more, 20 wt % or more, 21 wt % or more, 22 wt % or more, 23 wt % or more, or 24 wt % or more, and the upper limit thereof can be 90 wt % or less, 80 wt % or less, 70 wt % or less, 60 wt % or less, 50 wt % or less, 40 wt % or less, or 30 wt % or less. The encapsulation resin has good moisture barrier properties, but has a disadvantage that heat resistance durability is lowered, so that by adjusting the content of the encapsulation resin, the present application can maintain the heat resistance durability at high temperature and high humidity together while sufficiently realizing the moisture barrier performance of the resin itself.

In one example, the encapsulation film can comprise a moisture adsorbent. In this specification, the term “moisture adsorbent” can mean a chemically reactive adsorbent capable of removing moisture or humidity, for example, through chemical reaction with the moisture or humidity that has penetrated the encapsulation film, as described below.

In one example, an organic acid may not exist on the surface of the moisture adsorbent. In general, the moisture adsorbent may be surface-treated with a dispersant to be well dispersed in the composition, where the organic acid is present on the surface of the moisture adsorbent. Since such an organic acid permeates toward the element in the encapsulation layer in direct contact with the element, it may cause a white spot defect of the OLED panel. In the present application, the moisture adsorbent does not comprise a dispersant or does not comprise an organic acid, so that the reliability of the entire encapsulation composition is improved, thereby preventing OLED panel defects.

Here, the usable moisture adsorbent can include, for example, a metal oxide, a sulfate, or an organometallic oxide, and the like. Specifically, an example of the sulfate can include magnesium sulfate, sodium sulfate or nickel sulfate, and the like, and an example of the organometallic oxide can include aluminum oxide octylate and the like. Here, a specific example of the metal oxide can include phosphorus pentoxide (P₂O₅), lithium oxide (Li₂O), sodium oxide (Na₂O), barium oxide (BaO), calcium oxide (CaO) or magnesium oxide (MgO), and the like, and an example of the metal salt can include a sulfate such as lithium sulfate (Li₂SO₄), sodium sulfate (Na₂SO₄), calcium sulfate (CaSO₄), magnesium sulfate (MgSO₄), cobalt sulfate (CoSO₄), gallium sulfate (Ga₂(SO₄)₃), titanium sulfate (Ti(SO₄)₂) or nickel sulfate (NiSO₄), a metal halogenide such as calcium chloride (CaCl₂), magnesium chloride (MgCl₂), strontium chloride (SrCl₂), yttrium chloride (YCl₃), copper chloride (CuCl₂), cesium fluoride (CsF), tantalum fluoride (TaF₅), niobium fluoride (NbF₅), lithium bromide (LiBr), calcium bromide (CaBr₂), cesium bromide (CeBr₃), selenium bromide (SeBr₄), vanadium bromide (VBr₃), magnesium bromide (MgBr₂), barium iodide (BaI₂) or magnesium iodide (MgI₂); or a metal chlorate such as barium perchlorate (Ba(ClO₄)₂) or magnesium perchlorate (Mg(ClO₄)₂), and the like, but is not limited thereto. As the moisture adsorbent which can be contained in the encapsulation layer, one or two or more of the above-mentioned materials can be also used. In one example, when two or more are used as the moisture adsorbent, calcined dolomite and the like can be used.

Such a moisture adsorbent can be controlled to an appropriate size depending on the application. In one example, the average particle diameter of the moisture adsorbent can be controlled to 100 to 15000 nm, 500 nm to 10000 nm, 800 nm to 8000 nm, 1 μm to 7 μm, 2 μm to 5 μm or 2.5 μm to 4.5 μm. The moisture adsorbent having a size in the above range is easy to store because the reaction rate with moisture is not too fast, does not damage the element to be encapsulated. In this specification, the particle diameter can mean an average particle diameter, and can be one measured by a known method with a D50 particle size analyzer, unless otherwise specified.

The content of the moisture adsorbent is not particularly limited, which can be appropriately selected in consideration of the desired barrier properties. The moisture adsorbent can be included in an amount of 90 parts by weight or more relative to 100 parts by weight of the encapsulation resin, and as one example, can be included in the range of 93 to 800 parts by weight, 95 to 770 parts by weight, 97 to 750 parts by weight, 100 to 730 parts by weight, 103 to 700 parts by weight, 105 to 670 parts by weight, 110 to 650 parts by weight, 113 to 630 parts by weight, 115 to 600 parts by weight, 117 to 570 parts by weight, 120 to 530 parts by weight, 123 to 500 parts by weight, 125 to 480 parts by weight, 127 to 460 parts by weight, 130 to 440 parts by weight, 133 to 420 parts by weight, 135 to 400 parts by weight, 137 to 380 parts by weight, 140 to 360 parts by weight, 143 to 340 parts by weight, 145 to 320 parts by weight, 150 to 300 parts by weight, 153 to 290 parts by weight, 155 to 280 parts by weight, 158 to 270 parts by weight, or 160 to 260 parts by weight. That is, the encapsulation film according to the present application can exhibit excellent compatibility with other components in the encapsulation layer while comprising a larger amount of the moisture adsorbent than the conventional, and at the same time, can implement excellent moisture blocking effects by exhibiting excellent dispersibility even without a separate dispersant for the moisture adsorbent.

In one example, the encapsulation film can further comprise a tackifier. The tackifier can be, for example, a compound with a softening point of 70° C. or more, and in an embodiment, it can be 75° C. or more, 78° C. or more, 83° C. or more, 85° C. or more, 90° C. or more, or 95° C. or more, and the upper limit is not particularly limited, but can be 150° C. or less, 145° C. or less, 140° C. or less, 135° C. or less, 130° C. or less, or 125° C. or less. The tackifier can be a compound having a cyclic structure in the molecular structure, where the number of carbon atoms in the cyclic structure can be in the range of 5 to 15. The number of carbon atoms can be, for example, in the range of 6 to 14, 7 to 13, or 8 to 12. The cyclic structure can be a monocyclic compound, but is not limited thereto, which can be a bicyclic or tricyclic compound. The tackifier can also be an olefin-based polymer, where the polymer can be a homopolymer or a copolymer. In addition, the tackifier of the present application can be a hydrogenated compound. The hydrogenated compound can be a partially or fully hydrogenated compound. Such a tackifier can have excellent moisture barrier properties and have external stress relaxation properties, while having good compatibility with other components in the encapsulation film. A specific example of the tackifier can include a hydrogenated terpene-based resin, a hydrogenated ester-based resin or a hydrogenated dicyclopentadiene-based resin, and the like. The weight average molecular weight of the tackifier can be in the range of about 200 to 5,000 g/mol, 300 to 4,000 g/mol, 400 to 3,000 g/mol, or 500 to 2,000 g/mol. The content of the tackifier can be appropriately adjusted as necessary. For example, the content of the tackifier can be included in a ratio of 15 parts by weight to 200 parts by weight, 20 to 190 parts by weight, 25 parts by weight to 180 parts by weight or 30 parts by weight to 150 parts by weight relative to 100 parts by weight of the encapsulation resin. The present application can provide an encapsulation film having excellent moisture barrier properties and external stress relaxation properties by using the specific tackifier.

In the encapsulation film of the present application, the encapsulation layer can comprise a bright spot inhibitor. The bright spot inhibitor can have an adsorption energy of 0 eV or less for outgases, as calculated by an approximation method of the density functional theory. The lower limit of the adsorption energy is not particularly limited, but can be −20 eV. The type of the outgas is not particularly limited, but can include oxygen, H atoms, H₂ molecules and/or NH₃. As the encapsulation film comprises the bright spot inhibitor, the present application can prevent bright spots due to the outgas generated in the organic electronic device.

In an embodiment of the present application, the adsorption energy between the bright spot inhibitor and the bright spot-causing atoms or molecules can be calculated through electronic structure calculation based on the density functional theory. The above calculation can be performed by a method known in the art. For example, in the present application, after making a two-dimensional slab structure in which the closest packed filling surface of a bright spot inhibitor having a crystalline structure is exposed on the surface and then performing structure optimization, and performing the structure optimization for a structure that the bright spot-causing molecules are adsorbed on the surface of this vacuum state, the value obtained by subtracting the total energy of the bright spot-causing molecules from the total energy difference of these two systems was defined as the adsorption energy. For the total energy calculation about each system, a revised-PBE function as a function of GGA (generalized gradient approximation) series was used as exchange-correlation to simulate the interaction between electrons and electrons, the used cutoff of the electron kinetic energy was 500 eV and only the gamma point corresponding to the origin of the reciprocal space was included and calculated. A conjugate gradient method was used to optimize the atomic structure of each system and iterative calculation was performed until the interatomic force was 0.01 eV/Å or less. A series of calculation was performed through VASP as a commercially available code.

The material of the bright spot inhibitor is not limited as long as the material is a material having the effect of preventing the bright spots on the panel of the organic electronic device when the encapsulation film is applied to the organic electronic device. For example, the bright spot inhibitor can be a material capable of adsorbing a material exemplified by, for example, oxygen, H₂ gas, ammonia (NH₃) gas, H⁺, NH²⁺, NHR₂ or NH₂R as outgas generated from an inorganic deposition layer of silicon oxide, silicon nitride, or silicon oxynitride deposited on an electrode of an organic electronic element. Here, R can be an organic group, and for example, can be exemplified by an alkyl group, an alkenyl group, an alkynyl group and the like, but is not limited thereto.

In one example, the material of the bright spot inhibitor is not limited if it satisfies the above adsorption energy value, which can be a metal or a non-metal. The bright spot inhibitor can comprise, for example, Li, Ni, Ti, Rb, Be, Mg, Ca, Sr, Ba, Al, Zn, In, Pt, Pd, Fe, Cr, Si, or a formulation thereof, can comprise an oxide or a nitride of the material, and can comprise an alloy of the material. In one example, the bright spot inhibitor can comprise nickel particles, nickel oxide particles, titanium nitride, titanium-based alloy particles of iron-titanium, manganese-based alloy particles of iron-manganese, magnesium-based alloy particles of magnesium-nickel, rare earth-based alloy particles, carbon nanotubes, graphite, aluminophosphate molecular sieve particles or meso silica particles. The bright spot inhibitor can be included in an amount of 3 to 150 parts by weight, 6 to 143 parts by weight, 8 to 131 parts by weight, 9 to 123 parts by weight, 10 to 116 parts by weight, 10 parts by weight to 95 parts by weight, 10 parts by weight to 50 parts by weight, or 10 parts by weight to 35 parts by weight, relative to 100 parts by weight of the encapsulation resin. The present application can realize the bright spot prevention of the organic electronic device while improving adhesiveness and durability of the film in the above content range. In addition, the bright spot inhibitor can have a particle diameter in a range of 10 nm to 30 μm, 50 nm to 21 μm, 105 nm to 18 μm, 110 nm to 12 μm, 120 nm to 9 μm, 140 nm to 4 μm, 150 nm to 2 μm, 180 nm to 900 nm, 230 nm to 700 nm or 270 nm to 400 nm. The particle size can be according to D50 particle size analysis. By comprising the bright spot inhibitor, the present application can realize moisture barrier properties and endurance reliability of the encapsulation film together while efficiently adsorbing hydrogen generated in the organic electronic device.

Also, in one example, the encapsulation layer of the present application can comprise an active energy ray polymerizable compound which is highly compatible with the encapsulation resin and can form a specific cross-linked structure together with the encapsulation resin.

For example, the encapsulation layer of the present application can comprise a multifunctional active energy ray polymerizable compound that can be polymerized by irradiation of an active energy ray together with the encapsulation resin. The active energy ray polymerizable compound can mean a compound comprising two or more functional groups capable of participating in polymerization reaction by irradiation of an active energy ray, for example, functional groups containing an ethylenically unsaturated double bond such as an acryloyl group or a methacryloyl group, or functional groups such as an epoxy group or an oxetane group.

As the multifunctional active energy ray polymerizable compound, for example, a multifunctional acrylate (MFA) can be used.

In addition, the active energy ray polymerizable compound can be included in an amount of 0.5 parts by weight to 10 parts by weight, 0.7 parts by weight to 9 parts by weight, 1 part by weight to 8 parts by weight, 1.3 parts by weight to 7 parts by weight or 1.5 parts by weight to 6 parts by weight relative to 100 parts by weight of the encapsulation resin. The present application provides an encapsulation film having excellent endurance reliability even under severe conditions such as high temperature and high humidity in the above range.

The multifunctional active energy ray polymerizable compound which can be polymerized by irradiation of the active energy ray can be used without any limitation. For example, the compound can include 1,4-butanediol di(meth)acrylate, 1,3-butylene glycol di(meth)acrylate, 1,6-hexanediol di(meth)acrylate (HDDA), 1,8-octanediol di(meth)acrylate, 1,12-dodecanediol di(meth)acrylate, neopentylglycol di(meth)acrylate, dicyclopentanyl di(meth)acrylate, cyclohexane-1,4-diol di(meth)acrylate, tricyclodecanedimethanol di(meth)diacrylate, dimethyloldicyclopentane di(meth)acrylate, neopentylglycol-modified trimethylol propane di(meth)acrylate, admantane di(meth)acrylate, trimethylolpropane tri(meth)acrylate (TMPTA), or a mixture thereof.

As the multifunctional active energy ray polymerizable compound, for example, a compound having a molecular weight of 100 or more and less than 1,000 g/mol and containing two or more functional groups can be used. The ring structure included in the multifunctional active energy ray polymerizable compound can be any one of a carbocyclic structure or a heterocyclic structure; or a monocyclic or polycyclic structure.

In an embodiment of the present application, the encapsulation layer can further comprise a radical initiator. The radical initiator can be a photoinitiator or a thermal initiator. The specific kind of the photoinitiator can be appropriately selected in consideration of curing rate and yellowing possibility, and the like. For example, benzoin-based, hydroxy ketone-based, amino ketone-based or phosphine oxide-based photoinitiators, and the like can be used, and specifically, benzoin, benzoin methyl ether, benzoin ethyl ether, benzoin isopropyl ether, benzoin n-butyl ether, benzoin isobutyl ether, acetophenone, dimethylamino acetophenone, 2,2-dimethoxy-2-phenylacetophenone, 2,2-diethoxy-2-phenylacetophenone, 2-hydroxy-2-methyl-1-phenylpropan-1-one, 1-hydroxycyclohexylphenyl ketone, 2-methyl-1-[4-(methylthio)phenyl]-2-morpholino-propan-1-one, 4-(2-hydroxyethoxy)phenyl-2-(hydroxy-2-propyl) ketone, benzophenone, p-phenylbenzophenone, 4,4′-diethylaminobenzophenone, diclorobenzophenone, 2-methylanthraquinone, 2-ethylanthraquinone, 2-t-butylanthraquinone, 2-aminoanthraquinone, 2-methylthioxanthone, 2-ethylthioxanthone, 2-chlorothioxanthone, 2,4-dimethylthioxanthone, 2,4-diethylthioxanthone, benzyl dimethyl ketal, acetophenone dimethyl ketal, p-dimethylaminobenzoic acid ester, oligo[2-hydroxy-2-methyl-1-[4-(1-methylvinyl)phenyl]propanone] and 2,4,6-trimethylbenzoyl-diphenyl-phosphine oxide, and the like can be used.

The radical initiator can be included in a ratio of 0.2 parts by weight to 20 parts by weight, 0.5 to 18 parts by weight, 1 to 15 parts by weight, or 2 parts by weight to 13 parts by weight, relative to 100 parts by weight of the active energy ray polymerizable compound. As a result, the reaction of the active energy ray polymerizable compound can be effectively induced and deterioration of the physical properties of the encapsulation layer composition due to the residual components after curing can be also prevented.

In addition to the above-described constitutions, the encapsulation layer can comprise various additives depending on applications and the manufacturing process of the encapsulation film to be described below. For example, the encapsulation layer can comprise a curable material, a cross-linking agent, a filler, or the like in an appropriate range of content depending on the intended physical properties.

In one example, the encapsulation composition can have a viscosity measured at 170° C. and a shear rate of 50 s⁻¹ in a range of 1,000 to 2,000 Pa·s, and as one example, the lower limit of the viscosity can be 1,100 Pa·s or more, 1,200 Pa·s or more, 1,300 Pa·s or more, 1,400 Pa·s or more, or 1,500 Pa·s or more. Although not limited thereto, the viscosity can be a value measured by ARES (Advanced Rheometric Expansion System). As such, even though the encapsulation composition is a high-viscosity liquid, the present application can exhibit uniform dispersibility of the moisture adsorbent in the encapsulation composition through the extrusion process, as described above.

In an embodiment of the present application, the manufacturing method of the encapsulation film according to the present application can comprise a step of further comprising a metal layer formed on the encapsulation layer. That is, the encapsulation film can have a structure in which the encapsulation layer and the metal layer are laminated. The metal layer of the present application can have thermal conductivity of 20 W/m K or more, 50 W/m K or more, 60 W/m K or more, 70 W/m K or more, 80 W/m K or more, 90 W/m K or more, 100 W/m K or more, 110 W/m·K or more, 120 W/m·K or more, 130 W/m·K or more, 140 W/m·K or more, 150 W/m·K or more, 200 W/m·K or more, or 210 W/m·K or more. The upper limit of the thermal conductivity is not particularly limited, which can be 800 W/m·K or less. By having such high thermal conductivity, the heat generated at the bonding interface upon the metal layer bonding process can be released more quickly. Also, the heat accumulated during the operation of the organic electronic device is rapidly released because of the high thermal conductivity, whereby the temperature of the organic electronic device itself can be kept lower, and the occurrence of cracks and defects is reduced. The thermal conductivity can be measured at any temperature in the temperature range of 15 to 30° C.

The term “thermal conductivity” herein is a degree representing capability in which a material is capable of transferring heat by conduction, where the unit can be expressed by W/m·K. The unit represents the degree to which the material transfers heat at the same temperature and distance, which means a unit of heat (watt) to a unit of distance (meter) and a unit of temperature (Kelvin).

In an embodiment of the present application, the metal layer of the encapsulation film can be transparent or opaque. The metal layer can have a thickness in a range of 3 μm to 200 μm, 10 μm to 100 μm, 20 μm to 90 μm, 30 μm to 80 μm, or 40 μm to 75 μm. The present application can provide a thin film encapsulation film while realizing sufficient heat release effect by controlling the thickness of the metal layer. The metal layer can be a thin metal foil or a polymer base material layer deposited with metal. The metal layer is not particularly limited if it is a material satisfying the above-described thermal conductivity and containing a metal. The metal layer can comprise any one from a metal, a metal oxide, a metal nitride, a metal carbide, a metal oxynitride, a metal oxyboride, and a formulation thereof. For example, the metal layer can comprise an alloy in which one or more metal elements or nonmetal elements are added to one metal, and can comprise, for example, stainless steel (SUS). In addition, in one example, the metal layer can comprise iron, chromium, copper, aluminum, nickel, iron oxide, chromium oxide, silicon oxide, aluminum oxide, titanium oxide, indium oxide, tin oxide, indium tin oxide, tantalum oxide, zirconium oxide, niobium oxide and a formulation thereof. The metal layer can be deposited by means of electrolysis, rolling, thermal evaporation, electron beam evaporation, sputtering, reactive sputtering, chemical vapor deposition, plasma chemical vapor deposition or electron cyclotron resonance source plasma chemical vapor deposition. In one example of the present application, the metal layer can be deposited by reactive sputtering.

The encapsulation film can further comprise a base film or a release film (hereinafter, can be referred to as a “first film”), which can have a structure in which the encapsulation layer is formed on the base or release film. Also, the structure can further comprise a base film, a protective film or a release film (hereinafter, can be referred to as a “second film”) formed on the metal layer.

The specific kind of the first film that can be used in the present application is not particularly limited. In the present application, for example, a general polymer film in this field can be used as the first film. In the present application, for example, as the base or release film, a polyethylene terephthalate film, a polytetrafluoroethylene film, a polyethylene film, a polypropylene film, a polybutene film, a polybutadiene film, a polyvinyl chloride film, a polyurethane film, an ethylene-vinyl acetate film, an ethylene-propylene copolymer film, an ethylene-ethyl acrylate copolymer film, an ethylene-methyl acrylate copolymer film or a polyimide film, and the like can be used. In addition, a suitable mold release treatment can be performed on one side or both sides of the base film or release film of the present application. As an example of the releasing agent used in the releasing treatment of the base film, alkyd series, silicone series, fluorine series, unsaturated ester series, polyolefin series or wax series, and the like can be used, and among them, a releasing agent of alkyd series, silicone series or fluorine series is preferably used in terms of heat resistance, without being limited thereto.

In the present application, the thickness of the base film or release film (first film) as above is not particularly limited, which can be appropriately selected depending on the application to which it is applied. For example, in the present application, the thickness of the first film can be 10 μm to 500 μm, preferably, 20 μm to 200 μm or so. If the thickness is less than 10 μm, deformation of the base film can easily occur during the manufacturing process, whereas if it exceeds 500 μm, the economic efficiency is low.

The present application also relates to an organic electronic device.

As shown in FIG. 3, the organic electronic device (3) can comprise a substrate (31); an organic electronic element (32) formed on the substrate (31); and an encapsulation film manufactured according to the above-described manufacturing method for encapsulating the organic electronic element (32). The encapsulation film can comprise an encapsulation layer (33), and can also further comprise a metal layer (34). In this case, the encapsulation film integrally comprising the encapsulation layer (33) and the metal layer (34) can encapsulate the organic electronic element (32). When the encapsulation film comprises a metal layer, the organic electronic device can comprise a substrate (31); an organic electronic element (32); an encapsulation layer (33); and a metal layer (34) sequentially.

As one example, the encapsulation film can encapsulate the top surface, for example, all the upper part and the side surface, of the organic electronic element formed on the substrate. The encapsulation film can comprise an encapsulation layer containing a pressure-sensitive adhesive composition or an adhesive composition in a cross-linked or cured state. Furthermore, the organic electronic device can be formed by sealing the encapsulation layer so as to contact the top surface of the organic electronic element formed on the substrate.

In an embodiment of the present application, the organic electronic element can comprise a pair of electrodes, an organic layer containing at least a light emitting layer, and a passivation film. Specifically, the organic electronic element can comprise a first electrode layer, an organic layer formed on the first electrode layer and containing at least a light emitting layer, and a second electrode layer formed on the organic layer, and can comprise a passivation film for protecting the electrode on the second electrode layer and the organic layer. The first electrode layer can be a transparent electrode layer or a reflective electrode layer, and the second electrode layer can also be a transparent electrode layer or a reflective electrode layer. More specifically, the organic electronic element can comprise a transparent electrode layer formed on a substrate, an organic layer formed on the transparent electrode layer and containing at least a light emitting layer, and a reflective electrode layer formed on the organic layer.

Here, the organic electronic element can be, for example, an organic light emitting element.

The passivation film can comprise an inorganic film and an organic film. In one embodiment, the inorganic film can be one or more metal oxides or nitrides selected from the group consisting of Al, Zr, Ti, Hf, Ta, In, Sn, Zn and Si. The inorganic film can have a thickness of 0.01 μm to 50 μm or 0.1 μm to 20 μm or 1 μm to 10 μm. In one example, the inorganic film of the present application can be an inorganic material containing no dopant, or can be an inorganic material containing a dopant. The dopant which can be doped can be one or more elements selected from the group consisting of Ga, Si, Ge, Al, Sn, Ge, B, In, Tl, Sc, V, Cr, Mn, Fe, Co and Ni, or an oxide of the element, but is not limited thereto. The organic film is distinguished from the organic layer containing at least a light emitting layer in that it does not include a light emitting layer, and can be an organic deposition layer containing an epoxy compound.

The inorganic film or the organic film can be formed by chemical vapor deposition (CVD). For example, as the inorganic film, silicon nitride (SiNx) can be used. In one example, silicon nitride (SiNx) used as the inorganic film can be deposited to a thickness of 0.01 μm to 50 μm. In one example, the organic film can have a thickness in a range of 2 μm to 20 μm, 2.5 μm to 15 μm, or 2.8 μm to 9 μm.

The present application also provides a method of manufacturing an organic electronic device. The manufacturing method can comprise a step of applying the encapsulation film obtained from the manufacturing method to a substrate, on which an organic electronic element is formed, so as to cover the organic electronic element. In addition, the manufacturing method can comprise a step of curing the encapsulation film. The curing step of the encapsulation film can mean curing of the encapsulation layer, which can proceed before or after the encapsulation film covers the organic electronic element.

In this specification, the term “curing” can mean that the pressure-sensitive adhesive composition of the present invention forms a cross-linked structure through heating or UV irradiation processes, and the like to be produced in the form of a pressure-sensitive adhesive. Alternatively, it can mean that the adhesive composition is solidified and attached as an adhesive.

Specifically, the organic electronic element can be formed by forming a transparent electrode on a glass or polymer film used as a substrate by a method such as vacuum evaporation or sputtering, forming a luminescent organic material layer composed of, for example, a hole transporting layer, a light emitting layer and an electron transporting layer, and the like on the transparent electrode, and then further forming an electrode layer thereon. Subsequently, the encapsulation layer of the encapsulation film is placed to cover the top surface of the organic electronic element of the substrate subjected to the above process.

### Effects of Invention

The present application provides a method of manufacturing an encapsulation film that a structure capable of blocking moisture or oxygen flowing into an organic electronic device from the outside can be formed, and long-term reliability of the organic electronic device can be ensured.

However, the effects of the present invention are not limited to the effects mentioned above, and other effects not mentioned will be clearly understood by those skilled in the art from the description below.

### BRIEF DESCRIPTION OF DRAWINGS

FIG. 1 is a cross-sectional diagram showing an encapsulation layer according to one example of the present application.

FIG. 2 is a cross-sectional diagram showing an encapsulation film according to one example of the present application.

FIG. 3 is a cross-sectional diagram showing an organic electronic device according to one example of the present application.

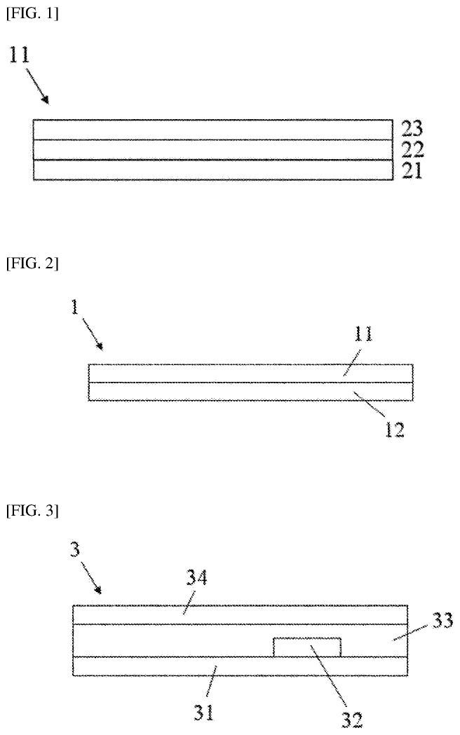

### EXAMPLES

Hereinafter, the present invention will be described in more detail through examples according to the present invention and comparative examples not according to the present invention, but the scope of the present invention is not limited by the following examples.

### Example 1

100 parts by weight of a butyl rubber resin (Mw: 410,000 g/mol, glass transition temperature: −65° C.), 100 parts by weight of a tackifying resin (SU525, softening point: 125° C., Kolon), 3 parts by weight of a multifunctional acrylate (tricyclodecane dimethanol diacrylate, Miwon), 1 part by weight of a photoinitiator (Irgacure 651, Ciba), and 200 parts by weight of CaO were put into a pressure kneader set at 150° C. and 20 bar, and then kneaded for about 30 minutes to prepare an encapsulation composition with a viscosity of 1500 Pa·s at 170° C. and a shear rate of 50 s⁻¹.

The encapsulation composition was transferred to a twin-screw extruder (SM Platek's TEK30) set at a temperature of 180° C. and a screw rotation speed of 250 rpm to be compounded, and extruded with a temperature of 160° C. and a pressure of 20 bar using a T-die mounted on the twin-screw extruder to prepare a film-shaped encapsulation layer with a thickness of 50 μm. An encapsulation film was manufactured by irradiating the encapsulation layer with 1.5 J/cm² ultraviolet rays.

### Example 2

An encapsulation layer was prepared in the same manner as in Example 1, except that the temperature of the T-die was set to 170° C.

Example 3

An encapsulation layer was prepared in the same manner as in Example 1, except that the temperature of the T-die was set to 180° C.

Comparative Example 1

100 parts by weight of a butyl rubber resin (Mw: 410,000 g/mol), 100 parts by weight of a tackifying resin (SU525, Melting point: 125° C., Kolon), 3 parts by weight of a multifunctional acrylate (tricyclodecane dimethanol diacrylate, Miwon), 1 part by weight of a photoinitiator (Irgacure 651, Ciba) and 200 parts by weight of CaO were blended to 600 parts by weight of toluene, and a dispersant (oleic Acid) was further introduced thereto in an amount of 0.5 parts by weight relative to 100 parts by weight of CaO, and mixed sufficiently to prepare a solution with a solid content of 40 wt %.

The solution was coated on release PET, dried in an oven at 120° C., and then irradiated with 1.5 J/m² ultraviolet rays to manufacture an encapsulation film.

### Comparative Example 2

An encapsulation layer was prepared in the same manner as in Example 1, except that the temperature of the twin-screw extruder was set to 120° C.

### Comparative Example 3

An encapsulation layer was prepared in the same manner as in Example 1, except that the temperature of the T-die was set to 120° C.

### Comparative Example 4

An encapsulation layer was prepared in the same manner as in Example 1, except that the pressure of the T-die was set to 10 bar.

### Comparative Example 5

An encapsulation layer was prepared in the same manner as in Example 1, except that the moisture adsorbent was included in 80 parts by weight.

### Experimental Example 1—Gel Content Measurement

Specimens with a size of 50 mm×50 mm were prepared from the encapsulation films of Examples and Comparative Examples, and 0.3 to 0.4 g of encapsulation film (initial weight: A) was taken for each encapsulation film specimen, and the encapsulation film was immersed in 70 g of toluene at 60° C. for 3 hours. Thereafter, the gel portion was filtered with a 200-mesh wire net (weight of wire net: M), and then dried in an oven at 125° C. for 1 hour. After measuring the combined weight (G) of the gel and the wire net, the dry mass (B=G−M) of the undissolved content of the encapsulation film that did not pass through the net, and the gel content (unit: %) according to General Equation 1 below were calculated.

$$Gel content ( unit : \% ) = ( B / A ) \times 100 \qquad [ General Equation 1 ]$$

In General Equation 1 above, A represents the initial mass of the encapsulation film specimen, and B represents the dry mass of an undissolved content of the encapsulation film, wherein after the encapsulation film specimen is immersed in 70 g of toluene at 60° C. for 24 hours, and then filtered through a 200-mesh (pore size 200 μm) net, the undissolved content does not pass through the net.

### Experimental Example 2—Measurement of Swelling Index

A certain amount of each of the encapsulation films according to Examples or Comparative Examples was put into a bottle, the bottle was filled with toluene, and stored for 24 hours to obtain a sol-gel solution. Hereinafter, the weight (X) of the gel sample was measured immediately after it was separated from the sol-gel solution using a 200 mesh (pore size 200 μm). The obtained gel sample was dried in an oven at 80° C. for 12 hours, and the weight (Y) of the gel sample was measured immediately after drying. The swelling index was calculated according to General Equation 2 below using the above values.

$$Swelling index = weight ( X ) of gel sample immediately after separation from sol - gel solution / weight ( Y ) of gel sample immediately after drying$$

### Experimental Example 3—Measurement of Storage Elastic Modulus

Each of the encapsulation films according to Examples or Comparative Examples was laminated to a thickness of 600 μm to obtain a specimen, and it was measured for the specimen using a parallel plate in the Temp Sweep mode of ARES (Advanced Rheometric Expansion System, TA's ARES-G2). Specifically, among the storage elastic moduli measured after applying a strain of 15.0 rad/s at a strain ratio of 0.1% to the specimen in a temperature range of 30 to 100° C., the values at a temperature of 50° C. were shown.

### Experimental Example 4—Measurement of Moisture Permeation Distance

After leaving the encapsulation films with 30 mm×60 mm of Examples and Comparative Examples in a constant temperature and humidity room at a temperature of 85° C. and 85% relative humidity for 895 hours, the distances through which moisture penetrated were measured with a microscope.

### Experimental Example 5—Metal Pressure-Sensitive Adhesion Force

Each of the encapsulation films according to Examples and Comparative Examples was thermally laminated on the Cu surface with a size of 200 mm×220 mm under a condition of 75° C., cut to 25 mm, and then further laminated on the Cu surface using a 2 Kg roller to prepare a specimen. After leaving the specimen in a constant temperature and humidity chamber at a temperature of 85° C. and 85% relative humidity for 30 minutes, it was fixed to a tensile machine, and the metal pressure-sensitive adhesion force was measured under the following measurement conditions.

### Measurement Conditions

Measuring instrument: Texture Analyzer
Mode: Tension Mode
Measurement temperature: 25° C.
Tensile rate: 5 mm/min

Table 1 shows the results of the experimental examples of the encapsulation films prepared in Examples and Comparative Examples.

TABLE 1

| | Example | | | Comparative Example | | | | |
|---|---|---|---|---|---|---|---|---|
| | 1 | 2 | 3 | 1 | 2 | 3 | 4 | 5 |
| Gel content | 78.1 | 78.3 | 77.9 | 71.2 | 74.5 | 74 | 74.7 | 79.8 |
| (%) | | | | | | | | |
| Swelling index | 469 | 453 | 450 | 567 | 612 | 590 | 620 | 421 |
| (%) | | | | | | | | |
| Storage elastic | 331,427 | 335,453 | 321,927 | 283,575 | 243,291 | 255,120 | 257,290 | 207,921 |
| modulus | | | | | | | | |
| (Pa) | | | | | | | | |
| Moisture | 1.8 | 1.8 | 1.8 | 2.2 | 2.4 | 2.3 | 2.2 | 2.6 |
| permeation distance | | | | | | | | |
| (mm) | | | | | | | | |
| Metal pressure- | 5,100 | 5,300 | 5,100 | 1,400 | 3,700 | 4,050 | 4,090 | 7,200 |
| sensitive adhesion | | | | | | | | |
| force | | | | | | | | |
| (gf/in) | | | | | | | | |

### EXPLANATION OF REFERENCE NUMERALS

1: encapsulation film
11: encapsulation layer
12: base material layer
3: organic electronic device
31: substrate
32: organic electronic element
33: encapsulation layer
34: metal layer

1. A method of manufacturing an encapsulation film, comprising:
preparing a solventless type encapsulation composition by mixing an encapsulation resin and a moisture adsorbent in a single step; and
preparing an encapsulation layer by extruding the encapsulation composition at a temperature of 90° C. or more.

2. The method of claim 1, wherein
the preparing the encapsulation composition by extruding is performed at a temperature of 50° C. or more and a pressure of 5 bar or more.

3. The method of claim 1, wherein
the preparingthe encapsulation layer by extruding is performed at a pressure of 5 bar or more.

4. The method of claim 1, wherein
the extruding is performed using a twin-screw extruder.

5. The method of claim 4, wherein
the twin-screw extruder has a screw rotation speed in a range of 100 to 400 rpm.

6. The method of claim 1, wherein
the encapsulation layer is a single layer or a multi-layered structure comprising two or more encapsulation layers.

7. The method of claim 1, wherein
the encapsulation layer has a gel content of 60% or more as measured by General Equation 1 below:
$$Gel content ( \% ) = A / B \times 100 \qquad [ General Equation 1 ]$$
wherein, B is the mass of the encapsulation layer sample, and A is the dry mass of an undissolved content of the encapsulation layer, wherein after the sample is immersed in toluene at 60° C. for 24 hours, and then filtered through a 200-mesh net, the undissolved content does not pass through the net.

8. The method of claim 1, wherein
the encapsulation resin comprises an olefinic resin.

9. The method of claim 1, wherein
the encapsulation resin is included in an amount of 10 wt % or more in an encapsulating material.

10. The method of claim 1, wherein
the moisture adsorbent is a chemically reactive adsorbent.

11. The method of claim 1, wherein
the moisture adsorbent is included in an amount of 90 parts by weight or more relative to 100 parts by weight of the encapsulation resin.

12. The method of claim 1, wherein
the encapsulation composition further comprises a tackifier.

13. The method of claim 12, wherein
the tackifier is included in a range of 15 to 200 parts by weight relative to 100 parts by weight of the encapsulation resin.

14. The method of claim 1, wherein
the encapsulation composition further comprises an active energy ray polymerizable compound.

15. The method of claim 14, wherein
the active energy ray polymerizable compound is included in a range of 0.5 to 10 parts by weight relative to 100 parts by weight of the encapsulation resin.

16. The method of claim 1, wherein
the encapsulation composition further comprises a radical initiator.

17. The method of claim 1, wherein
the encapsulation composition has a viscosity measured at 170° C. and a shear rate of 50 s⁻¹ in a range of 1,000 to 2,000 Pa·s.

18. The method of claim 1, wherein the encapsulation layer is in direct contact with an organic electronic element.

19. (canceled)

20. An organic electronic device, comprising: a substrate; an organic electronic element formed on the substrate; and an encapsulation film manufactured according to the method of claim 1 encapsulating the organic electronic element.

21. A method of manufacturing an organic electronic device, comprising applying the encapsulation film manufactured according to the method of claim 1 to a substrate, on which an organic electronic element is formed, to cover the organic electronic element.
